(19) United States
(12) Patent Application Publication
(10) Pub. No.: US 2024/0321614 A1
(43) Pub. Date: Sep. 26, 2024

(54) VALVE COVER AND SUBSTRATE CARRIER USING THE SAME

(71) Applicant: Gudeng Precision Industrial Co, Ltd., New Taipei City (TW)

(72) Inventors: MING-CHIEN CHIU, New Taipei City (TW); EN-NIEN SHEN, New Taipei City (TW); CHIA-HO CHUANG, New Taipei City (TW); KUO-HUA LEE, New Taipei City (TW); JYUN-MING LYU, New Taipei City (TW)

(21) Appl. No.: 18/519,139

(22) Filed: Nov. 27, 2023

Related U.S. Application Data
(60) Provisional application No. 63/454,173, filed on Mar. 23, 2023.

(51) Int. Cl. H01L 21/673; H01L 21/67

(52) U.S. Cl. CPC H01L 21/67386; H01L 21/67017; H01L 21/67393

(57) ABSTRACT

A valve cover for using in a substrate carrier includes a main body and plural elastic arms. The substrate carrier has a shell and a base disposed on a bottom of the shell. A purge valve is received at the bottom and a gas opening is provided on the base. The main body of the valve cover is disposed on the base, and the elastic arms are disposed on the main body and located at the gas opening. The elastic arms are used for fixing the valve cover between the bottom of the shell and the base. A top face of the valve cover is lower than a surface height of the base and a surface height of the purge valve.

### RELATED APPLICATIONS

This application claims priority to U.S. Provisional Patent Application No. 63/454,173, by CHIU, et al., titled “Quick Release Purge Valve Cover and Semiconductor Container Using The Same,” filed on Mar. 23, 2023, which is hereby incorporated by reference in their entirety.

### BACKGROUND OF THE INVENTION

### Technical Field

The present invention relates to a valve cover and a substrate carrier using the same. More particularly, the present invention relates to a valve cover and a substrate carrier that are used in the field of semiconductors.

### Description of Related Art

Along with the development of technology, the fabrication process of semiconductor elements also evolves. Especially, with the trend of miniaturization of linewidth, semiconductor elements are now becoming even smaller and have higher logic density. Therefore, any defects present on the semiconductor element or any particles attached thereon will have a significant impact on the yield rate of the fabricating process.

To maintain the cleanliness and to protect the semiconductor elements during the fabricating process, a kind of substrate carrier like the front opening unified pod (FOUP) has been developed. A batch of plural semiconductor elements can be transported in the substrate carrier at the same time. The efficiency of the fabricating process can therefore be increased. However, the contaminants from the outside will enter the carrier when the door of the substrate carrier is opened. It is therefore an important subject on how to maintain the internal cleanliness of the substrate carrier.

One known method is to install numerous air valves and provide a gas of a certain flow rate to pass through the air valves. The flow rate is provided in such a manner that the air exchange rate inside the carrier can be maintained and thus the particle number inside can be reduced. Each air valve is surrounded by an elastic rubber and is installed onto the shell of the carrier through the interference between the pre-pressed elastic rubber and the gas inlet or outlet. Nevertheless, in this installation mechanism, the air valves may fall out of the shell easily when they are subject to external collisions or during purging operations on purging platform, making it difficult to perform the purging process properly.

It is therefore an urgent problem that the industry seeks to resolve to prevent the air valves from falling out of the substrate carrier.

### SUMMARY

In view of the above-mentioned problems, the present invention is to provide a valve cover and a substrate carrier using the same. The valve cover includes a main body and plural elastic arms. The elastic arms are disposed at a gas opening of a base, so a purge valve can be fixed between the bottom of the shell and the base. Since the purge valve is fixed properly, problems like the purge valve falling out of the shell can be prevented and the purging operation can be performed properly. By using the elastic arms, the purge valve can also be installed and removed easily, and the overall efficiency of the fabrication process can be increased.

According to one aspect of the invention, a valve cover is provided. The valve cover is used for implementing in a substrate carrier, and the carrier has a shell and a base disposed on a bottom of the shell. A purge valve is received at the bottom, and a gas opening is provided on the base. The valve cover includes a main body and plural elastic arms. The main body of the valve cover is disposed on the base. The elastic arms are disposed on the main body and located at the gas opening. The elastic arms are used for fixing the purge valve between the bottom of the shell and the base. A top face of the valve cover is lower than a surface height of the base and a surface height of the purge valve.

In one embodiment, the top face of the valve cover is lower than the surface height of the base or the surface height of the purge valve by more than 1 mm.

In another embodiment, each of the elastic arms has a elastic angle in relation to the main body and the elastic angle is from 0° to 90°.

In yet another embodiment, the main body of the valve cover is a ring. One side of each elastic arm is connected to an outer side of the ring for abutting against the purge valve, and the other side of each elastic arm extends toward the gas opening for contacting a lateral side of the base so that each elastic arm is partly situated on the base, thereby having the elastic arms detachably connect to the gas opening.

In another embodiment, each elastic arm is provided with a hook portion and the purge valve is provided with a limiting portion. The hook portion faces the gas opening and engages with the lateral side of the base, and a location where the elastic arms are connected to the outer side of the ring is used for abutting against the limiting portion.

In one embodiment, the base is provided with a recession recessed from an edge of the gas opening, and the hook portion is engaged with the base through the recession. An engagement region where the hook portion overlaps with the base is from 0.8 mm to 1.5 mm.

In another embodiment, the ring has a width sufficient for abutting against the limiting portion of the purge valve, and the width is defined by an inner diameter of the ring which is from 25 mm to 26.5 mm and an outer diameter of the ring which is 25.1 mm to 28.5 mm.

In yet another embodiment, the main body of the valve cover is provided with a covering portion which is located below the elastic arms and away from the gas opening. The covering portion is used for covering a portion of the purge valve.

In one embodiment, one side of each elastic arm is configured by extending from the base toward the gas opening, and the other side of each elastic arm connects with the main body of the valve cover. The main body is used for abutting against the purge valve.

According to another aspect of the invention, a substrate carrier is provided. The substrate carrier includes a shell, a base, and the previously mentioned valve cover. The shell has a bottom for receiving a purge valve. The base is disposed on the bottom of the shell, and a gas opening is provided on the base for receiving a portion of the purge valve. A surface height of the purge valve is lower than or equal to a surface height of the base. The valve cover is disposed between the bottom of the shell and the base for fixing the purge valve from falling out of the gas opening.

According to the disclosure of the embodiments of the invention, the main body of the valve cover is disposed between the bottom of the shell and the base through the elastic arms, so the problems like the purge valve falling out of the shell during transportation or during the purging operation, can be prevented. The purging operation can be performed properly on the substrate carrier. In addition, by using the elastic arms, the convenience of replacing the purge valve can also be increased.

### BRIEF DESCRIPTION OF DRAWINGS

The invention can be more fully understood by reading the following detailed description of the embodiment, with reference made to the accompanying drawings as follows:

FIG. 1 is a three-dimensional diagram of a substrate carrier according to one embodiment of the invention;

FIG. 2 is an exploded diagram of the substrate carrier of FIG. 1;

FIG. 3 is a schematic diagram of the valve cover, the shell, and the base;

FIG. 4 is a three-dimensional diagram of a valve cover according to one embodiment of the invention;

FIG. 5 is a schematic diagram of a side view of the valve cover;

FIG. 6 is a schematic diagram of a top view of the valve cover;

FIG. 7 is a partial sectional view of a valve cover, a shell, and a base according to another embodiment of the invention; and

FIG. 8 is a partial sectional view of a valve cover, a shell, and a base according to a further embodiment of the invention.

### DETAILED DESCRIPTION

According to the embodiments of the invention, a valve cover and a substrate carrier using the same are provided. The valve cover includes a main body and plural elastic arms. The elastic arms are located at a gas opening for fixing a purge valve between a base and a bottom of a shell. A top face of the valve cover is lower than a surface height of the base and a surface height of the purge valve. The purge valve is properly fixed by the valve cover, and therefore can be prevented from falling out of the gas opening. The purging operation can be performed properly, and the efficiency of the fabrication process can be increased.

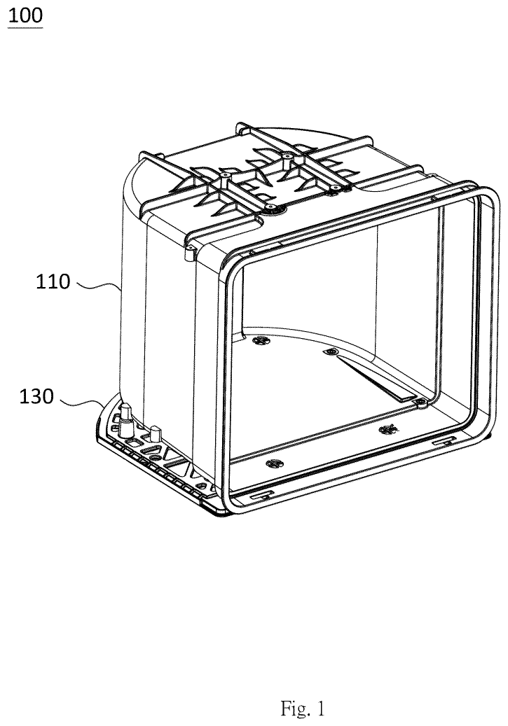

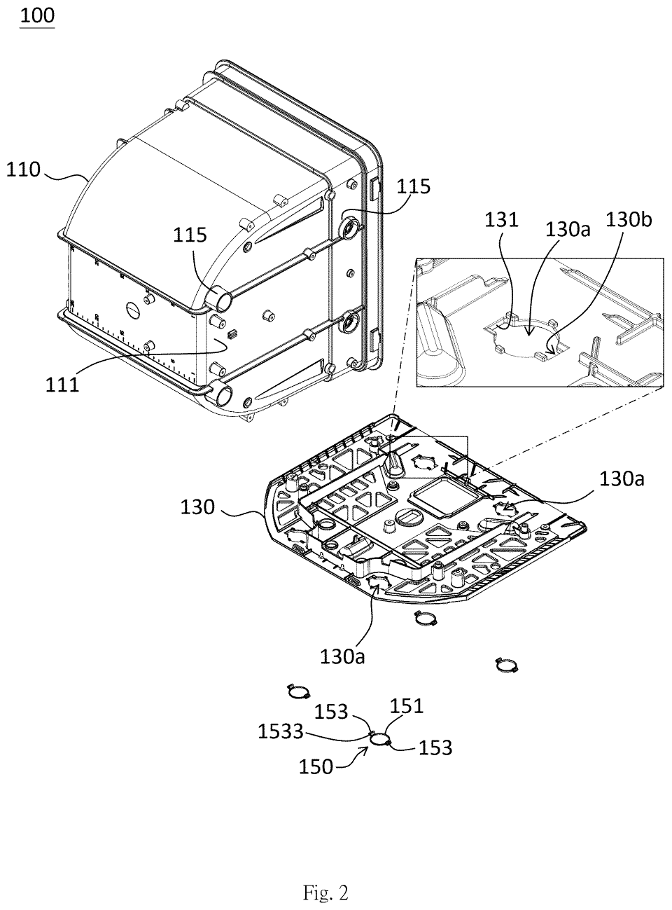

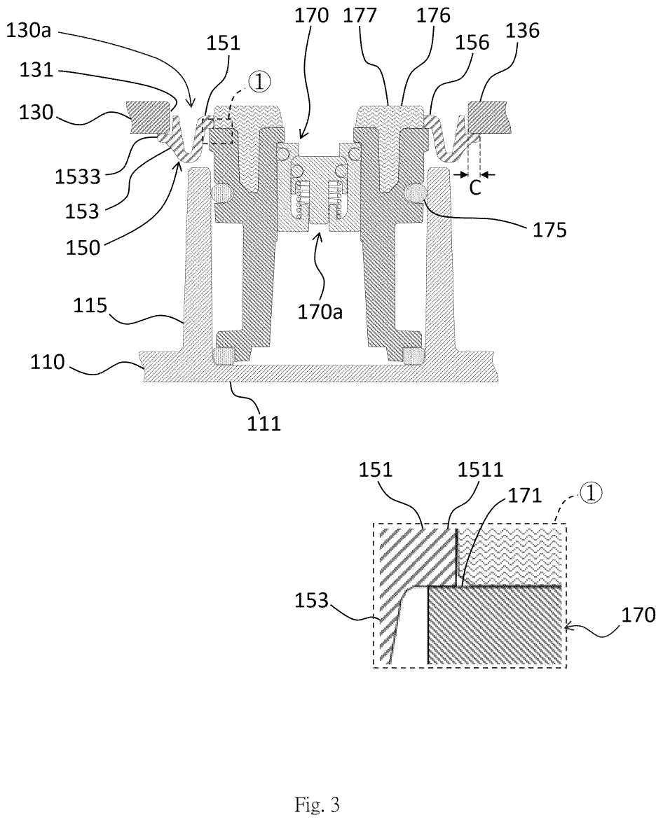

Please refer to FIG. 1 to FIG. 3. FIG. 1 is a three-dimensional diagram of a substrate carrier according to one embodiment of the invention. FIG. 2 is an exploded diagram of the substrate carrier of FIG. 1. FIG. 3 is a schematic diagram of the valve cover, the shell, and the base. The substrate carrier 100 of the present embodiment includes a shell 110, a base 130, and a valve cover 150. The shell 110 has a bottom 111 for receiving a purge valve 170. The base 130 is disposed on the bottom 111 of the shell 110. A gas opening 130a is provided on the base 130 for partially accommodating the purge valve 170. The surface height 176 of the purge valve 170 is lower than or equal to a surface height 136 of the base 130. The valve cover 150 includes a main body 151 and plural elastic arms 153. The elastic arms 153 are disposed on the main body 151 of the valve cover 150 and are located at the gas opening 130a for fixing the purge valve 170 between the base 130 and the bottom 111 of the shell 110.

As shown in FIG. 2, the present embodiment is exemplified by four valve covers 150 and four gas openings 130a. A part of the gas openings 130a is used for letting a gas enter the shell 110 (i.e., gas inlet, let the gas enter the accommodating space of the shell 110 for accommodating plural substrates). The other part of the gas openings 130a is used for letting the gas leave the shell 110 (i.e., gas outlet, let the gas leave the accommodating space). In the present embodiment. Two of the gas openings 130a are used as the gas inlet and the other two are used as the gas outlet. However, in practical use, the number of the gas openings 130a as the gas inlet or outlet can be changed based on the needs of the purging operation, and the number of the valve covers 150 can be changed accordingly.

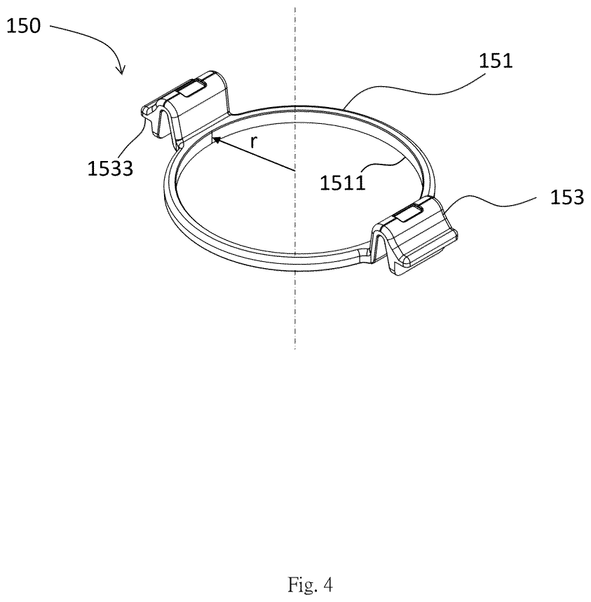

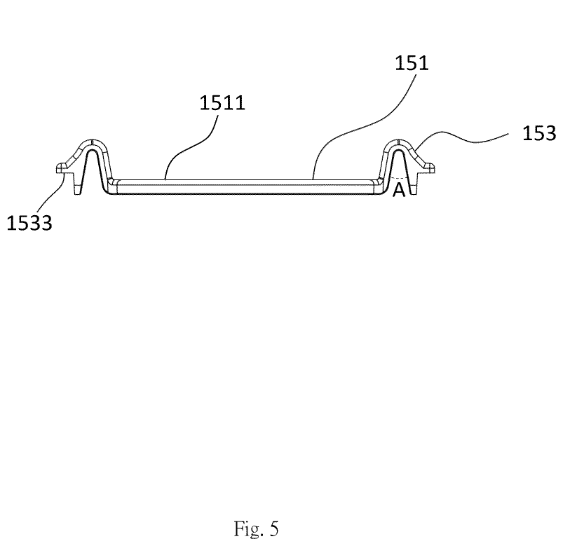

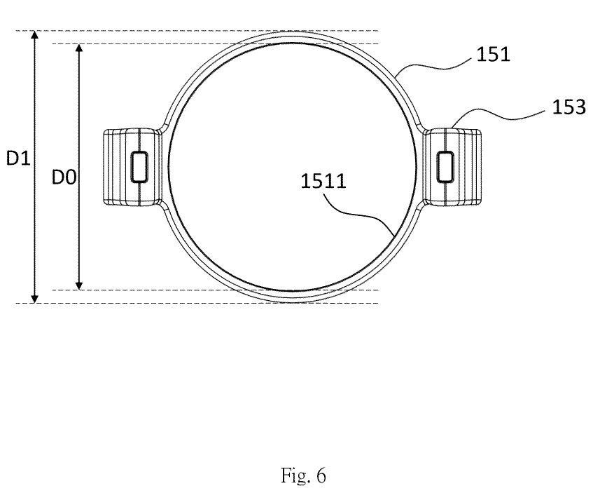

Please refer to FIG. 3 to FIG. 6. FIG. 4 is a three-dimensional diagram of a valve cover according to one embodiment of the invention. FIG. 5 is a schematic diagram of a side view of the valve cover. FIG. 6 is a schematic diagram of a top view of the valve cover. The main body 151 of the valve cover 150 of the present embodiment is a ring 1511. One side of each elastic arm 153 is connected to an outer side of the ring 1511 for abutting against the purge valve 170. The other side of each elastic arm 153 extends toward the gas opening 130a for contacting a lateral side 131 of the base 130 so that each elastic arm 153 is partly situated on the base 130, thereby having the elastic arm 153 detachably connects to the gas opening 130a. Each elastic arm 153 extends outwardly in a radius direction r of the ring 1511 and detachably engages with the gas opening 130a of the base 130. In one embodiment, each elastic arm 153 is exemplified by a U-shaped hook whose one side is connected to the ring 1511 and the other side is used for elastically engaging with the base 130. An elastic angle A is formed between each elastic arm 153 and the main body 151. The elastic angle A can be any angle from 0 degree to 90 degrees. The smaller the elastic angle A is, the shorter distance each elastic arm 153 travels, which provides a more rigid structure, and the engagement between the elastic arm 153 and the base 130 can be more firmly. On the contrary, the larger the elastic angle A is, the greater distance each elastic arm 153 travels, which provides a more flexible structure, and the valve cover 150 can be released more easily. In practical use, the elastic angle A can be determined based on the material of the elastic arms 153 or the flow rate required by the purging operation, so as to balance between the engagement force and the easiness of releasing the valve cover 150.

On the other hand, a pair of elastic arms 153 is shown in the embodiment. The pair of the elastic arms 153 fall on opposite radius directions r, which poses a 180-degree-angle therebetween. However, the invention is not limited thereto. In another embodiment, there can be three or more elastic arms 153. When three elastic arms 153 are presented, each two can have a 120-degree-angel therebetween. When four elastic arms 153 are presented, the angle between two adjacent elastic arms 153 can be 90 degrees. Although the elastic arms 153 described here are all equal-distantly arranged, they can also be arranged in different interval angles, depending on actual structural needs.

Each elastic arm 153 is provided with a hook portion 1533, and the purge valve 170 is provided with a limiting portion 171. The hook portion 1533 faces the gas opening 130a and engages with the lateral side 131 of the base 130. A location where the elastic arms 153 connect to the outer side of the ring 1511 is used for abutting against the limiting portion 171. Since said location is used for abutting the limiting portion 171, the firmness of fixing the purge valve 170 is highly related to the size of the ring 1511, and the purging operation will also be affected by the size of the ring 1511. In one embodiment, the ring 1511 has a width sufficient for abutting against the limiting portion 171. The width is defined by an inner diameter DO and an outer diameter D1. The inner diameter DO of the ring 1511 is slightly smaller than the size of the abutted limiting portion 171 and is close to the size of the valve rubber 177 of the purge valve 170. (The details of the valve rubber 170 will be elaborated later.) When the inner diameter DO is smaller, the purge valve 170 is less likely to fall off. When the inner diameter DO is larger, the ring 1511 is less likely to interfere with the valve rubber 177. In practical use, the inner diameter DO can also be determined based on the size of an external purge nozzle. In one embodiment, the inner diameter DO is around 25.0 mm to around 26.5 mm, so a good fixing effect of the purge valve 170 can be achieved, and such size also conforms to a purging area of the external purge nozzle. Besides that, an outer diameter D1 of the ring 1511 is around 25.1 mm to around 28.5 mm.

As shown in FIG. 3, the valve rubber 177 is further included in the purge valve 170. The valve rubber 177 is used for coupling with the external nozzle and is disposed on one side of the purge valve 170 near the gas opening 130a. A top face 156 of the valve cover 150 is lower than the surface height 136 of the base 130 and the surface height 176 of the purge valve 170. To be more specific, in one embodiment, the top face 156 is lower than the surface height 136 of the base 130 or the surface height 176 of the purge valve 170 by more than 1.0 mm, so that a safe buffer distance is kept and a stable purging operation on the purging platform can be performed. So, when the external purge nozzle docks with the valve rubber 177 and performs the purging operation, the valve cover 150 will not interfere with the nozzle. The air-tightness at this location can be maintained and the purging operation can be performed properly.

On the other hand, please refer to FIG. 2 and FIG. 3. The base 130 is provide with a recession 130b recessed from an edge of the gas opening 130a. The hook portion 1533 is engaged with the base 130 through the recession 130b, and an engagement region C where the hook portion 1533 overlaps with the base 130 is from about 0.8 mm to about 1.5 mm. The elastic arms 153 can be well engaged with the base 130 and at the same time can be removed by the user easily. A good assemble/disassemble relation is achieved.

A receiving portion 115 is provided on the bottom 111 of the shell 110 for receiving the purge valve 170. The purge valve 170 can be exemplified by a check valve, and an elastic grommet 175 surrounds the outside of the purge valve 170. When the purge valve 170 is received in the receiving portion 115, the elastic grommet 175 tightly contacts the receiving portion 115 to form an air-tight state. The gas can only enter or leave the shell 110 though a gas channel 170a located in the center of the purge valve 170, so the problems relating to leakage can be prevented.

According to the valve cover 150 of the present embodiment, the elastic arms 153 are disposed at the gas opening 130a of the base 130 so the purge valve 170 can be fixed between the base 130 and the bottom 111 of the shell 110. Problems like the purge valve 170 falling out of the gas opening 130a during transportation or during purging operation can be prevented. The purging operation can be performed on the substrate carrier 100 properly. Additionally, the use of the elastic arms 15 also facilitates the convenience of replacing the purge valve 170.

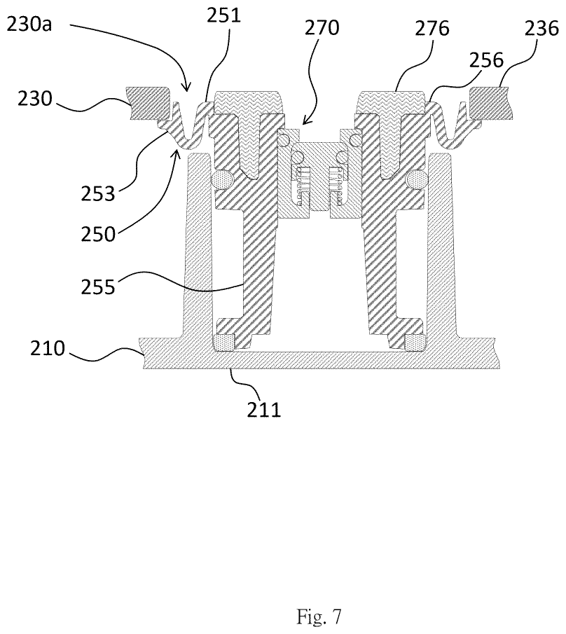

Please refer to FIG. 7, which is a partial sectional view of a valve cover, a shell, and a base according to another embodiment of the invention. The valve cover 250 includes a main body 251 and plural elastic arms 253. The main body 251 is disposed on the base 230, and the elastic arms 253 are disposed on the main body 251 and located at an gas opening 230a of the base 230. The elastic arms 253 are used for fixing a purge valve 270 between a bottom 211 of the shell 210 and the base 230. A top face 256 of the valve cover 250 is lower than a surface height 276 of the purge valve 270.

The main body 251 of the valve cover 250 of the present embodiment is provided with a covering portion 255 which is located below the elastic arms 253 and away from the gas opening 230a. The covering portion 255 is used for covering a portion of the purge valve 270. The elastic arms 253 of the present embodiment can be exemplified by having the same structure as the elastic arms 153 of previous-described embodiments relating to FIG. 1 to FIG. 6. Their details will not be repeated here.

According to the valve cover 250 of the present embodiment, the elastic arms 253 are disposed at the gas opening 230a, so the valve cover 250 can be used for fixing the purge valve 270 between the base 230 and the shell 210. The purge valve 270 can be prevented from falling off, and the purging operation can be performed properly. Additionally, the convenience of replacing the purge valve 270 can be increased.

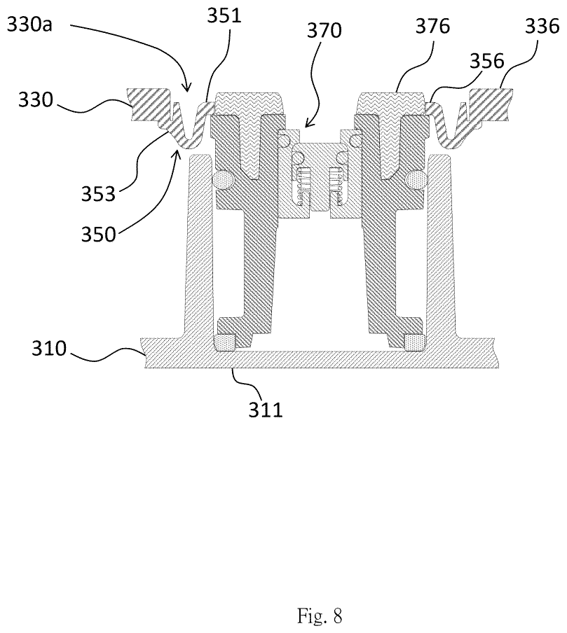

Please refer to FIG. 8, which is a partial sectional view of a valve cover, a shell, and a base according to a further embodiment of the invention. The valve cover 350 includes a main body 351 and plural elastic arms 353 disposed on the main body 351. The elastic arms 353 are located at a gas opening 330a of the base 330, so the valve cover 350 is used for fixing a purge valve 370 between the shell 310 and the base 330. A top face 356 of the valve cover 350 is lower than a surface height 336 of the base 330 and a surface height 376 of the purge valve 370.

In the present embodiment, one side of each elastic arm 353 is configured by extending from the base 330 toward the gas opening 330a, and the other side of each elastic arm 353 connects the main body 351 of the valve cover 350. The main body 351 is used for abutting against the purge valve 370. A lateral side of the base 330 which faces toward the gas opening 330a, the elastic arms 353, and the main body 351 are formed in one piece. Each of the elastic arms 353 has an elastic angle A, and its detail and structure can be the same as those shown in FIG. 5 and related descriptions. One side of each elastic arm 353 is connected to the main body 351 and the other side is abutting against a limiting portion of the purge valve 370. The limiting portion here can be the same as the limiting portion 171 of the purge valve 170 of FIG. 3. The elastic arms 353 of the present embodiment are provided with structures similar to the elastic arms 153 of FIG. 1 to FIG. 6. The main body 351 of the valve cover 350 in the present embodiment, although not being a physical ring structure here, still provides the same technical effect and achieves the same technical result through the same technical means as previous-mentioned structures.

According to the valve cover 350 of the present embodiment, the elastic arms 353 are located at the gas opening 330a so the valve cover 350 can be used for fixing the purge valve 370. Problems like the purge valve 370 falling out of the shell 310 though the gas opening 330a can be prevented, and the purging operation can be performed properly. The convenience of replacing the purge valve 370 can be increased.

The valve cover and the substrate carrier using the same of the 1o above-mentioned embodiments include the main body of the valve cover and the elastic arms. The valve cover is either an independent element or integrated as a part of the base. Through the disposition of the elastic arms at the gas opening, the purge valve can be fixed between the base and the bottom of the shell. The problem of the purge valve falling out of the gas opening is prevented. Additionally, the top face of the valve cover is lower than the surface height of the base and the surface height of the purge valve, which is advantageous for the purging operation to be performed properly. Furthermore, by using the elastic arms, the valve cover can be removed easily, hence increasing the convenience of replacing the purge valve.

The ordinal numbers used in the detailed description and claims, such as “first” and “second” do not necessarily indicate their priority orders or up and down directions; on the contrary, they are merely intended to distinguish different members. It will be apparent to those skilled in the art that various modifications and variations can be made to the structure of the present invention without departing from the scope or spirit of the invention. In view of the foregoing, it is intended that the present invention covers modifications and variations of this invention, provided they fall within the scope of the following claims.

What is claimed is:

1. A valve cover for using in a substrate carrier having a shell and a based disposed on a bottom of the shell, a purge valve being received at the bottom and a gas opening being provided on the base, the valve cover comprising:
a main body of the valve cover disposed on the base; and
a plurality of elastic arms disposed on the main body and located at the gas opening, the elastic arms being used for fixing the purge valve between the bottom of the shell and the base;
wherein, a top face of the valve cover is lower than a surface height of the base and a surface height of the purge valve.

2. The valve cover according to claim 1, wherein the top face of the valve cover is lower than the surface height of the base or the surface height of the purge valve by more than 1 mm.

3. The valve cover according to claim 1, wherein each of the elastic arms has an elastic angle in relation to the main body, and the elastic angle is from 0° to 90°.

4. The valve cover according to claim 1, wherein the main body of the valve cover is a ring, one side of each elastic arm is connected to an outer side of the ring for abutting against the purge valve, and the other side of each elastic arm extends toward the gas opening for contacting a lateral side of the base, so that each elastic arm is partly situated on the base, thereby having the elastic arms detachably connect to the gas opening.

5. The valve cover according to claim 4, wherein each elastic arm is provided with a hook portion and the purge valve is provided with a limiting portion, and the hook portion faces the gas opening and engages with the lateral side of the base, and a location where the elastic arms connect to the outer side of the ring is used for abutting against the limiting portion.

6. The valve cover according to claim 5, wherein the base is provided with a recession recessed from an edge of the gas opening, the hook portion is engaged with the base through the recession, and an engagement region where the hook portion overlaps with the base is from 0.8 mm to 1.5 mm.

7. The valve cover according to claim 4, wherein the ring has a width sufficient for abutting against the limiting portion of the purge valve, and the width is defined by an inner diameter of the ring which is from 25 mm to 26.5 mm and an outer diameter of the ring which is 25.1 mm to 28.5 mm.

8. The valve cover according to claim 1, wherein the main body of the valve cover is provided with a covering portion which is located below the elastic arms and away from the gas opening, and the covering portion is used for covering a portion of the purge valve.

9. The valve cover according to claim 1, wherein one side of each elastic arm is configured by extending from the base toward the gas opening and the other side of each elastic arm connects the main body of the valve cover, and the main body is used for abutting against the purge valve.

10. A substrate carrier, comprising:
a shell having a bottom for receiving a purge valve;
a base disposed on the bottom of the shell, a gas opening being provided on the base for receiving a portion of the purge valve, wherein a surface height of the purge valve is lower than or equal to a surface height of the base; and
the valve cover according to claim 1;
wherein, the valve cover is disposed between the bottom of the shell and the base for fixing the purge valve from falling out of the gas opening.
